(19) United States
(12) Patent Application Publication
(10) Pub. No.: US 2026/0179690 A1
(43) Pub. Date: Jun. 25, 2026

(54) MEMORY DEVICE AND METHOD OF OPERATING THE SAME

(71) Applicant: Samsung Electronics Co., Ltd., Suwon-si (KR)

(72) Inventors: Haechan Lee, Suwon-si (KR); NA-YOUNG CHOI, Suwon-si (KR); DONGWOOK KIM, Suwon-si (KR); JONGRYUL KIM, Suwon-si (KR); JI-SANG LEE, Suwon-si (KR); SUNG-MIN JOE, Suwon-si (KR)

(21) Appl. No.: 19/403,981

(22) Filed: Nov. 30, 2025

(30) Foreign Application Priority Data
Dec. 19, 2024 (KR) 10-2024-0191850

(51) Int. Cl. G11C 16/10; G11C 16/04; G11C 16/34

(52) U.S. Cl. CPC G11C 16/10; G11C 16/0483; G11C 16/3459

(57) ABSTRACT

A memory device includes a memory cell array including a plurality of cell strings disposed on a substrate and a peripheral circuit configured to perform a program operation on a plurality of string select lines vertically disposed on the substrate. The peripheral circuit may be configured to simultaneously perform a program operation on at least two string select lines of the plurality of string select lines corresponding to one of the plurality of cell strings and arranged in a direction perpendicular to. Each of the plurality of cell strings includes a plurality of string select transistors, a plurality of memory cells, and one or more ground select transistors connected in series. Each of the plurality of string select transistors is connected to a corresponding string select line of the plurality of string select lines.

### CROSS-REFERENCE TO RELATED APPLICATION(S)

This U.S. non-provisional application claims priority under 35 USC § 119 to Korean Patent Application No. 10-2024-0191850, filed on Dec. 19, 2024, in the Korean Intellectual Property Office, the disclosure of which is herein incorporated by reference in its entirety.

### BACKGROUND

The present disclosure relates to a memory device and a method of operating the same.

Memory devices are used to store data and are classified into volatile memory devices and non-volatile memory devices. A flash memory device, an example of a non-volatile memory device, may be used in mobile phones, digital cameras, portable computer devices, stationary computer devices, or other devices.

With the increasing demand for lower operating voltages in memory devices, the threshold voltage distribution of string select lines needs improvement.

### SUMMARY

One or more embodiments provide a memory device configured to improve a threshold voltage distribution of string select lines by simultaneously programming at least two string select lines, and a method of operating the memory device.

According to one or more embodiments, a memory device includes a memory cell array including a plurality of cell strings disposed on a substrate and a peripheral circuit configured to perform a program operation on a plurality of string select lines corresponding to one of the plurality of cell strings and arranged in a direction perpendicular to the substrate. The peripheral circuit may be configured to simultaneously perform a program operation on at least two string select lines of the plurality of string select lines. Each of the plurality of cell strings includes a plurality of string select transistors, a plurality of memory cells, and one or more ground select transistors connected in series. Each of the plurality of string select transistors is connected to a corresponding string select line of the plurality of string select lines.

According to one or more embodiments, a method of operating a memory device including a plurality of cell strings each including a plurality of string select transistors, a plurality of memory cells, and one or more ground select transistors connected in series, each of the plurality of string select transistors connected to a corresponding string select line of a plurality of string select lines, the plurality of cell strings disposed on a substrate includes selecting at least two string select lines from among the plurality of string select lines corresponding to one of the plurality of cell strings and arranged in a direction perpendicular to the substrate, and simultaneously performing a program operation on the selected at least two string select lines.

According to one or more embodiments, a storage device includes a plurality of non-volatile memory devices comprising a plurality of cell strings disposed on a substrate and a solid-state drive (SSD) controller configured to control the plurality of non-volatile memory devices. At least one of the plurality of non-volatile memory devices may be configured to perform a program operation on a plurality of string select lines corresponding to one of the plurality of cell strings and arranged in a direction perpendicular to the substrate, and simultaneously perform a program operation on at least two string select lines among the plurality of string select lines. Each of the plurality of cell strings includes a plurality of string select transistors, a plurality of memory cells, and one or more ground select transistors connected in series. Each of the plurality of string select transistors is connected to a corresponding string select line of the plurality of string select lines.

### BRIEF DESCRIPTION OF DRAWINGS

FIG. 1 is a block diagram of a memory device according to one or more embodiments.

FIG. 2 is a circuit diagram of a single memory block, among a plurality of memory blocks included in a memory cell array of FIG. 1 according to one or more embodiments.

FIG. 3 is a diagram illustrating an example of a first cell string illustrated in FIG. 2 according to one or more embodiments.

FIG. 4 is a flowchart illustrating a program operation and a verify read operation on a plurality of string select lines according to one or more embodiments.

FIG. 5A is a diagram illustrating bias conditions applied to string select lines and wordlines during a program operation according to one or more embodiments.

FIG. 5B is a timing diagram for the program operation according to one or more embodiments.

FIG. 6A is a diagram illustrating bias conditions applied to string select lines and wordlines during a verify read operation according to one or more embodiments.

FIG. 6B is a timing diagram for the verify read operation according to one or more embodiments.

FIG. 7A is a diagram illustrating a threshold voltage distribution of string select transistors when a program operation and a verify read operation are individually performed on each of a plurality of string select lines.

FIG. 7B is a diagram illustrating a threshold voltage distribution of string select transistors when a merge program operation and a merge verify read operation are performed on a plurality of string select lines according to one or more embodiments.

FIG. 8 is a flowchart illustrating a program operation and a verify read operation on a plurality of string select lines according to one or more embodiments.

FIG. 9A is a diagram illustrating bias conditions applied to string select lines and wordlines during a first program operation and a first verify read operation according to one or more embodiments.

FIG. 9B is a diagram illustrating changes in distribution during the first program operation and the first verify read operation according to one or more embodiments.

FIG. 9C is a diagram illustrating bias conditions applied to string select lines and wordlines during the first program operation and the first verify read operation according to one or more embodiments.

FIG. 9D is a diagram illustrating changes in distribution during the first program operation and the first verify read operation according to one or more embodiments.

FIG. 10A is a diagram illustrating bias conditions applied to string select lines and wordlines during a second program operation and a second verify read operation according to one or more embodiments.

FIG. 10B is a diagram illustrating changes in distribution during the second program operation and the second verify read operation according to one or more embodiments.

FIG. 11 is a circuit diagram of a single memory block, among a plurality of memory blocks included in the memory cell array of FIG. 1.

FIG. 12 is a diagram illustrating an example of a program operation and a verify read operation on a plurality of string select lines performed by the memory device of FIG. 1 according to one or more embodiments.

FIG. 13A is a diagram illustrating an example of a program operation and a verify read operation on a plurality of string select lines according to FIG. 12 according to one or more embodiments.

FIGS. 13B and 13C are diagram illustrating bias conditions applied to string select lines and wordlines during a first program operation and a first verify read operation according to one or more embodiments.

FIG. 13D are a diagram illustrating bias conditions applied to string select lines and wordlines during a second program operation and a second verify read operation according to one or more embodiments.

FIG. 14A is a diagram illustrating an example of a program operation and a verify read operation on a plurality of string select lines according to FIG. 12 according to one or more embodiments.

FIGS. 14B and 14C are diagrams illustrating bias conditions applied to string select lines and wordlines during a first program operation and a first verify read operation according to one or more embodiments.

FIG. 14D is a diagram illustrating bias conditions applied to string select lines and wordlines during a second program operation and a second verify read operation according to one or more embodiments.

FIG. 15A is a diagram illustrating an example of a program operation and a verify read operation on a plurality of string select lines according to FIG. 12 according to one or more embodiments.

FIGS. 15B and 15C are diagrams illustrating bias conditions applied to string select lines and wordlines during a first program operation and a first verify read operation according to one or more embodiments.

FIG. 15D is a diagram illustrating bias conditions applied to string select lines and wordlines during a second program operation and a second verify read operation according to one or more embodiments.

FIG. 16 is a block diagram of a storage system according to one or more embodiments.

### DETAILED DESCRIPTION

Hereinafter, example embodiments will be described in detail to enable those skilled in the art to readily implement the present disclosure.

In the present disclosure, the terms such as “first” and “second” as used herein may modify various elements regardless of an order and/or importance of the corresponding elements, and do not limit the corresponding elements. These terms may be used for the purpose of distinguishing one element from another element.

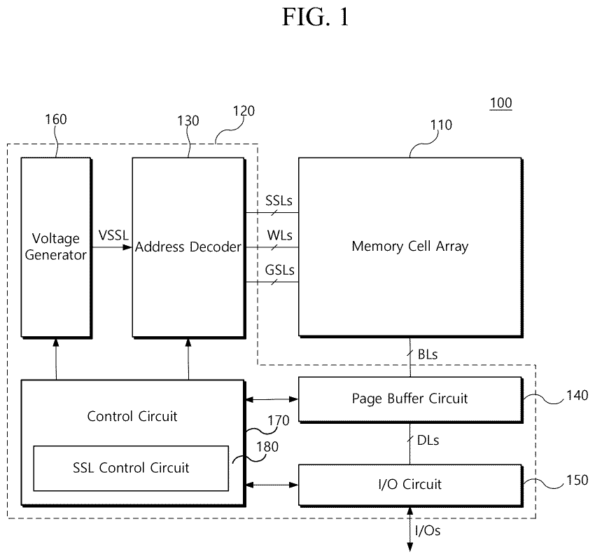

FIG. 1 is a block diagram of a memory device according to one or more embodiments.

Referring to FIG. 1, a memory device 100 may include a memory cell array 110 and a peripheral circuit 120. The peripheral circuit 120 may include an address decoder 130, a page buffer circuit 140, an input/output (I/O) circuit 150, a voltage generator 160, and a control circuit 170.

The memory cell array 110 may be connected to the address decoder 130 through wordlines WLs, string select lines SSLs, or ground select lines GSLs. The memory cell array 110 may be connected to the page buffer circuit 140 through bitlines BLs.

The memory cell array 110 may include a plurality of memory blocks. Each memory block may have a two-dimensional structure or a three-dimensional structure. In a memory block having a two-dimensional structure (or a horizontal structure), memory cells may be arranged in a direction parallel to a substrate. In a memory block having a three-dimensional structure (or a vertical structure), memory cells may be arranged in directions parallel and perpendicular to the substrate. The memory cells may be non-volatile memory cells.

Each memory block may include a plurality of cell strings. In certain embodiments, a cell string may be a NAND cell string, and a channel of each cell string may be formed in a direction perpendicular to the substrate.

In certain embodiments, a cell string may include a plurality of string select transistors connected in series, a plurality of memory cells, and one or more ground select transistors. Each string select transistor may be connected to a corresponding string select line, among the plurality of string select lines SSLs. Each of the plurality of memory cells may be connected to a corresponding wordline. The ground select transistor may be connected to a ground select line.

In certain embodiments, at least two string select lines may be arranged in a direction perpendicular to the substrate. Each cell string may correspond to at least two string select lines arranged in the direction perpendicular to the substrate.

The address decoder 130 may select one of the plurality of memory blocks in response to the control of the control circuit 170. For example, the address decoder 130 may select at least one of the plurality of string select lines SSLs during a program operation or a verify read operation on a string select line.

A program operation on a string select line may refer to a program operation on string select transistors connected to the string select line. A verify read operation on a string select line may refer to a verify read operation on a string select transistors connected to the string select line.

The address decoder 130 may receive a string select line voltage VSSL from the voltage generator 160. The string select line voltage VSSL may include a program voltage for a program operation on a string select line and a verify read voltage for a verify read operation on a string select line. The address decoder 130 may provide the program voltage or the verify read voltage to a selected string select line.

The page buffer circuit 140 may be connected to the memory cell array 110 through bitlines BLs. The page buffer circuit 140 may temporarily store data to be stored in the memory cell array 110 or data read from the memory cell array 110.

The input/output circuit 150 may be internally connected to the page buffer circuit 140 through data lines DLs and externally connected to a memory controller through input/output lines I/Os.

The voltage generator 160 may generate various voltages required for the operation of the memory device 100 under the control of the control circuit 170. For example, the voltage generator 160 may generate voltages to be supplied to wordlines WLs, string select lines SSLs, and ground select lines GSLs.

The voltage generator 160 may generate voltages used for a program operation or a verify read operation on the string select lines. For example, the string select line voltage VSSL provided to the string select lines SSLs may include a program voltage, a verify read voltage, a pass voltage, a read pass voltage, or the like.

The control circuit 170 may control the overall operation of the memory device 100. The control circuit 170 may include a string select line control circuit 180.

The string select line control circuit 180 may control the memory device 100 to perform a program operation and/or a verify read operation on a string select line.

The string select line control circuit 180 according to one or more embodiments may support a merge program operation on at least two string select lines that correspond to the same cell string and are arranged in a direction perpendicular to the substrate. The merge program operation may refer to a program operation performed substantially simultaneously on at least two string select lines that correspond to the same cell string and are arranged in a direction perpendicular to the substrate.

In certain embodiments, the merge program operation may be performed on all of the plurality of string select lines arranged in a direction perpendicular to the substrate. Alternatively, in certain embodiments, the merge program operation may be performed on a portion of the plurality of string select lines arranged in a direction perpendicular to the substrate. The merge program operation on a portion of the plurality of string select lines may be referred to as a partial merge program operation.

The string select line control circuit 180 according to one or more embodiments may support a merge verify read operation on at least two string select lines arranged in a direction perpendicular to the substrate. The merge verify read operation may refer to a verify read operation performed substantially simultaneously on at least two string select lines arranged in a direction perpendicular to the substrate.

In certain embodiments, the merge verify read operation may be performed on all of the plurality of string select lines arranged in a direction perpendicular to the substrate. Alternatively, in certain embodiments, the merge verify read operation may be performed on a portion of the plurality of string select lines arranged in a direction perpendicular to the substrate. A merge verify read operation on a portion of the plurality of string select lines may be referred to as a partial merge verify read operation.

The string select line control circuit 180 according to one or more embodiments may perform a program operation on each string select line, a plurality of times. At least one of the program operations performed the plurality of times may be a merge program operation or a partial merge program operation.

In certain embodiments, a first program operation may be performed on a plurality of string select lines arranged in a direction perpendicular to the substrate. The first program operation may be an individual program operation on each string select line. Then, a second program operation may be performed on the plurality of string select lines. The second program operation may be a merge program operation on all of the plurality of string select lines.

In certain embodiments, a first program operation may be performed on a plurality of string select lines arranged in a direction perpendicular to the substrate. The first program operation may include a partial merge program operation on a portion of the plurality of string select lines and an individual program operation on each of the remaining string select lines. Then, a second program operation may be performed on the plurality of string select lines. The second program operation may be a merge program operation on all of the plurality of string select lines.

In addition, the string select line control circuit 180 according to one or more embodiments may perform a verify read operation on each string select line, a plurality of times. At least one of the verify read operations performed the plurality of times may be a merge verify read operation or a partial merge verify read operation.

In certain embodiments, a first program operation may be performed on a plurality of string select lines arranged in a direction perpendicular to the substrate, and a first verify read operation corresponding to the first program operation may be performed. The first verify read operation may be an individual verify read operation on each string select line. Then, a second program operation may be performed on the plurality of string select lines, and a second verify read operation corresponding to the second program operation may be performed. The second verify read operation may be a merge verify read operation on all of the plurality of string select lines.

Alternatively, in certain embodiments, the first verify read operation may include a partial merge verify read operation on a portion of the plurality of string select lines and an individual verify read operation on each of the remaining string select lines. The second verify read operation may be a merge verify read operation on all of the plurality of string select lines.

However, this is only an example, and embodiments are not limited thereto. For example, during the first program operation and/or the second program operation, an individual program operation may be performed on a portion of the string select transistors, and a partial merge program operation may be performed on the remaining string select transistors. Similarly, during the first verify read operation and/or the second verify read operation, an individual verify read operation may be performed on a portion of the string select transistors and a partial merge verify read operation may be performed on the remaining string select transistors.

As described above, the memory device 100 according to one or more embodiments may include a plurality of string select lines that correspond to the same cell string and are arranged in a direction perpendicular to the substrate. The memory device 100 may perform a program operation on at least two of the plurality of string select lines substantially simultaneously. Alternatively, the memory device 100 may perform a verify read operation on at least two of the plurality of string select lines substantially simultaneously. As a result, a distribution of the threshold voltage of the string select lines may be improved.

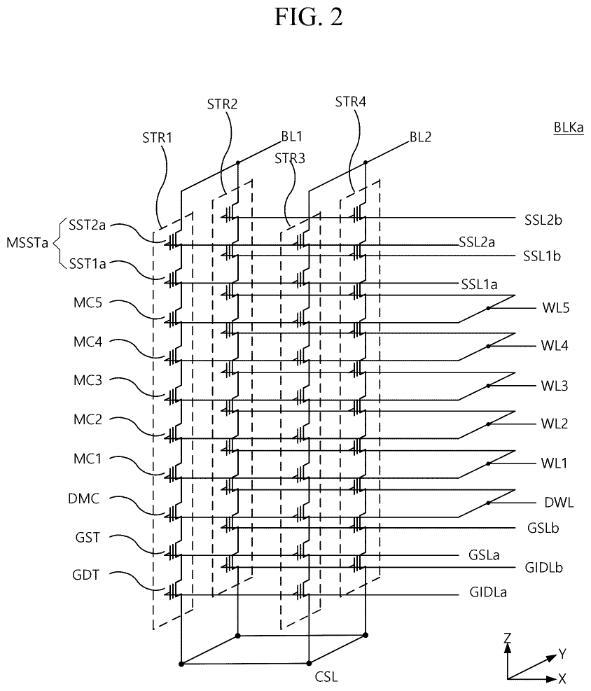

FIG. 2 is a circuit diagram of a single memory block, among a plurality of memory blocks included in a memory cell array of FIG. 1 according to one or more embodiments. For clarity, an example is provided in which a single memory block includes four cell strings STR1 to STR4, and a string select transistor SST is disposed at uppermost ends of the strings STR1 to STR4.

Referring to FIG. 2, a memory block BLKa may include a plurality of cell strings STR1 to STR4, vertically stacked on a substrate. Each of the plurality of cell strings STR1 to STR4 may be arranged in a first direction (an X-axis direction) and a second direction (a Y-axis direction).

Among the plurality of cell strings STR1 to STR4, strings disposed in the same column may be connected to the same bitline. For example, the first and second cell strings STR1 and STR2 may be connected to a first bitline BL1, and the third and fourth cell strings STR3 and STR4 may be connected to a second bitline BL2.

Each of the plurality of cell strings STR1 to STR4 may include a plurality of cell transistors. Each of the plurality of cell transistors may be a charge trap flash (CTF) memory cell, but embodiments are not limited thereto. The plurality of cell transistors may be stacked in a third direction (a Z-axis direction).

The plurality of strings STR1 to STR4 may be commonly connected to a common source line CSL. For example, the common source line CSL may be commonly connected to lower ends of the plurality of cell strings STR1 to STR4, as illustrated in FIG. 2. However, this is only an example, and it is sufficient for the common source line CSL to be electrically connected to the lower ends of the cell strings STR1 to STR4, and embodiments are not limited to being physically disposed at the lower ends of the cell strings STR1 to STR4. Hereinafter, for clarity, the structure and configuration of the string will be described with reference to the first cell string STR1. The other cell strings STR2, STR3, and STR4 may have a structure similar to that of the first cell string STR1, and a detailed description thereof will be omitted.

In the first cell string STR1, a plurality of cell transistors may be connected in series between the first bitline BL1 and the common source line CSL. For example, the plurality of cell transistors may include a plurality of string select transistors SST2a and SST1a, memory cells MC1 to MC5, a dummy memory cell DMC, ground select transistors GST, and a GIDL transistor GDT.

The plurality of string select transistors SST2a and SST1a may be disposed at an uppermost end of the cell string STR1. The string select transistor SST2a may be connected to the first bitline BL1 at the uppermost end of the cell string STR1. With respect to a single cell string, each of the plurality of string select transistors may be connected to a corresponding string select line among a plurality of string select lines. For example, a gate of the string select transistor SST2a may be connected to the string select line SSL2a, and a gate of the string select transistor SST1a may be connected to the string select line SSL1a.

The GIDL transistor GDT may be disposed at the lowermost end of the string STR1. For example, the GIDL transistor GDT may be connected to the common source line CSL at a lower end of the string STR1.

A single ground select transistor GST may be provided between the dummy memory cell DMC and the GIDL transistor GDT. A gate of the ground select transistor GST may be connected to the ground select line GSLa. However, this is only an example. In certain embodiments, a plurality of ground select transistors connected in series may be provided between the dummy memory cell DMC and the GIDL transistor GDT.

The first to fifth memory cells MC1 to MC5 may be connected in series between the string select transistor SST1a and the dummy memory cell DMC. Gates of the first to fifth memory cells MC1 to MC5 may be connected to the first to fifth wordlines WL1 to WL5, respectively.

A single dummy memory cell DMC may be provided between the first memory cell MC1 and the GIDL transistor GDT. A gate of the dummy memory cell DMC may be connected to a dummy wordline DWL. However, this is only an example. In certain embodiments, a plurality of dummy memory cells connected in series may be provided between the first memory cell MC1 and the GIDL transistor GDT. Alternatively, an additional dummy memory cell may be provided between the string select transistor SST1a and the fifth memory cell MC5. Alternatively, an additional dummy memory cell may be provided between the memory cells MC1 to MC5. Alternatively, the dummy memory cell DMC may not be provided.

In certain embodiments, a program operation on two string select lines SSL2a and SSL1a corresponding to the single cell string STR1 may be performed substantially simultaneously. The string select transistors SST2a and SST1a, on which the program operation is performed simultaneously, may be referred to as merge string select transistors MSSTa.

In certain embodiments, a verify read operation on two string select lines SSL2a and SSL1a corresponding to the single cell string STR1 may be performed substantially simultaneously.

In certain embodiments, a program operation on the string select lines SSL2a and SSL1a may be performed a plurality of times. For example, a first program operation and a second program operation may be performed sequentially. In the first program operation, a program operation on each of the string select lines SSL2a and SSL1a may be performed individually. In the second program operation, program operations on the two string select lines SSL2a and SSL1a may be performed substantially simultaneously.

In certain embodiments, a verify read operation on the string select lines SSL2a and SSL1a may be performed a plurality of times. For example, a first program operation on the string select lines SSL2a and SSL1a may be performed, and a first verify read operation corresponding to the first program operation may be performed. Then, a second program operation on the string select lines SSL2a and SSL1a may be performed, and a second verify read operation corresponding to the second program operation may be performed. In the first verify read operation, a verify read operation on each of the string select lines SSL2a and SSL1a may be performed individually. In the second verify read operation, verify read operations on the two string select lines SSL2a and SSL1a may be performed substantially simultaneously.

FIG. 2 illustrates a case in which a single cell string includes two string select transistors, and the two string select transistors are adjacent to each other. However, this is only an example. In certain embodiments, a single cell string may include three or more string select transistors. A merge program operation may be performed on string select lines corresponding to string select transistors that are spaced apart from each other (for example, not adjacent to each other). For example, the merge program operation may be performed on string select lines adjacent to each other in a direction vertical to the substrate, or on string select lines that are not adjacent to each other.

When a single cell string includes three or more string select transistors, a program operation and/or a verify read operation may be performed substantially simultaneously on a portion of the three or more string select lines and a program operation and/or a verify read operation may be performed individually on the remaining string select lines. The string select lines, on which the program operation and/or the verify read operation are performed substantially simultaneously, may be string select lines that are adjacent to each other in a direction perpendicular to the substrate, or string select lines that are not adjacent to each other.

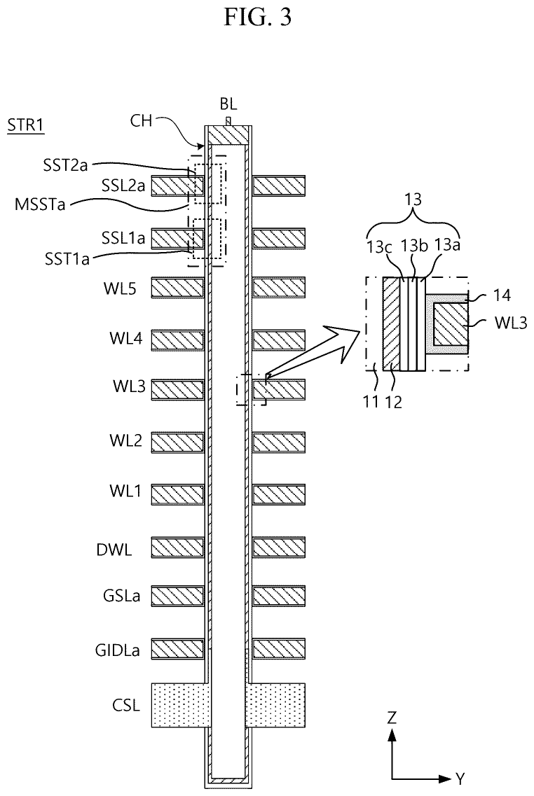

FIG. 3 is a diagram illustrating an example of the cell string STR1 illustrated in FIG. 2 according to one or more embodiments.

Referring to FIG. 3, the cell string STR1 may include a channel structure CH. The channel structure CH may include a vertical channel layer 12, a buried insulating layer 11 filling a space inside the vertical channel layer 12, and a vertical insulating layer 13 disposed between the vertical channel layer 12 and row lines. The row lines may include string select lines SSL2a and SSL1a, first to fifth wordlines WL1 to WL5, a dummy wordline DWL, a ground select line GSLa, a GIDL line GIDLa, a common source line CSL, or the like. In certain embodiments, the channel structure CH may have an inclined side surface with a diameter decreasing toward the substrate. Alternatively, in certain embodiments, the channel structure CH may have an inclined side surface with a diameter increasing toward the substrate. Alternatively, in certain embodiments, the cell string STR1 may include two or more channel structures CHs stacked in a vertical direction.

The vertical channel layer 12 may include a semiconductor material such as polysilicon or single-crystal silicon. For example, the semiconductor material may be an undoped material. In certain embodiments, the vertical channel layer 12 may have a pillar shape, such as a cylinder or prism, without the buried insulating layer 11. The vertical insulating layer 13 may include a blocking layer 13a, a charge storage layer 13b, and a tunnel insulating layer 13c.

The blocking layer 13a may be interposed between the charge storage layer 13b and the row lines. At least a portion of the blocking layer 13a may be formed to surround the row lines and provided as a blocking layer 14. The blocking layer 13a may include a material with a larger energy band gap than the charge storage layer 13b. For example, the blocking layer 13a may be a silicon oxide layer, a silicon nitride layer, and/or a silicon oxynitride layer.

The charge storage layer 13b may be interposed between the blocking layer 13a and the tunnel insulating layer 13c. For example, the charge storage layer 13b may include at least one of a silicon nitride, a silicon oxynitride, a silicon-rich nitride, nanocrystalline silicon, or a laminated trap layer.

The tunnel insulating layer 13c may be interposed between the charge storage layer 13b and the vertical channel layer 12. The tunnel insulating layer 13c may include a material with a larger band gap than the charge storage layer 13b. For example, the tunnel insulating layer 13c may be a silicon oxide layer.

The plurality of row lines may be alternately stacked on the common source line CSL. The plurality of row lines may include, for example, a metal such as polysilicon (Poly-Si) or tungsten (W) and/or a conductive metal nitride.

Continuing to refer to FIG. 3, regions respectively corresponding to the string select transistors SST2a and SST1a are illustrated, and a region corresponding to the merge string select transistor MSSTa is illustrated. For example, the string select transistor SST2a may be defined as a region corresponding to the string select line SSL2a, and the string select transistor SST1a may be defined as a region corresponding to the string select line SSL1a. The merge string select transistor MSSTa may be defined as regions corresponding to the two string select lines SSL2a and SSL1a. For example, when the same level of voltage is provided to the string select lines SSL2a and SSL1a substantially simultaneously, the string select transistors SST2a and SST1a may operate as a single merge string select transistor MSSTa.

According to one or more embodiments, the same program voltage is applied to the string select lines SSL2a and SSL1a substantially simultaneously, so that the string select transistors SST2a and SST1a may be programmed as if they were a single merge string select transistor MSSTa. Electrons may be evenly distributed between the two regions corresponding to the string select transistors SST2a and SST1a to improve lateral spreading.

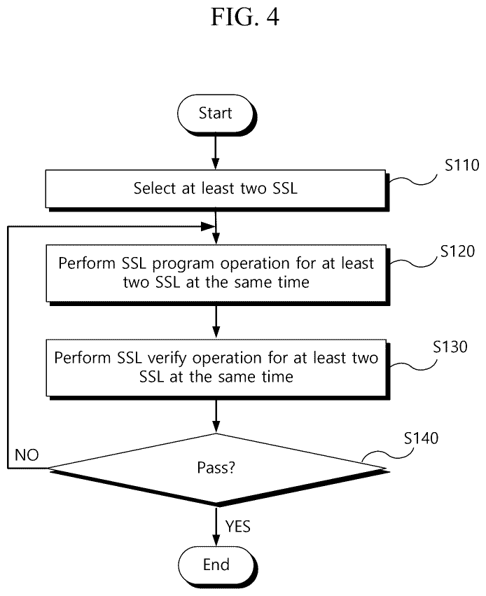

FIG. 4 is a flowchart illustrating a program operation and a verify read operation on a plurality of string select lines according to one or more embodiments.

In operation S110, among the plurality of string select lines, at least two string select lines may be selected.

For example, all or a portion of the plurality of string select lines, which correspond to the same cell string and are arranged in a direction perpendicular to the substrate, may be selected.

For example, referring to FIGS. 1 and 2, the peripheral circuit 120 may select two string select lines SSL2a and SSL1a. However, this is only an example, and embodiments are not limited thereto. For example, when a single cell string includes three string select transistors, for example, when three string select lines correspond to a single cell string, the peripheral circuit 120 may select two or three string select lines from among the three string select lines. The peripheral circuit 120 may select string select lines that are spaced apart from each other (for example, not adjacent to each other) or string select lines that are adjacent to each other.

In operation S120, a program operation on at least two string select lines may be performed substantially simultaneously.

For example, program voltages may be applied substantially simultaneously to the string select lines selected in operation S110, respectively. The program voltages applied to the string select lines may be substantially the same.

For example, referring to FIGS. 1 and 2, the peripheral circuit 120 may simultaneously apply program voltages to the string select lines SSL2a and SSL1a. The program voltages applied to the string select lines SSL2a and SSL1a may be transmitted to gates of the string select transistors SST2a and SST1a. Threshold voltages of the string select transistors SST2a and SST1a after programming may be substantially the same.

In operation S130, a verify read operation on at least two string select lines may be performed simultaneously.

For example, verify read voltages may be applied substantially simultaneously to the string select lines programmed simultaneously in operation S120, respectively. The verify read voltages applied to the string select lines may be the same.

For example, referring to FIGS. 1 and 2, the peripheral circuit 120 may simultaneously apply verify read voltages to the string select lines SSL2a and SSL1a, respectively. The verify read voltages applied to the string select lines SSL2a and SSL1a may be transmitted to the gates of the string select transistors SST2a and SST1a.

In operation S140, a determination may be made as to whether the program operation on the string select lines has been completed, based on a result of the verify read operation.

For example, when a threshold voltage of a string select transistor programmed in operation S120 is equal to or greater than the verify read voltage, it may be determined that the program operation on the string select transistor has been completed.

When it is determined that the program operation on the string select transistor has been completed (‘Yes’ direction), the program operation on the selected string select transistor may be completed. When it is determined that the program operation on the selected string select transistor has not been completed (‘No’ direction), the flow returns to operation S120. In this case, the applied program voltage may be the same as or slightly higher than the previously applied program voltage.

As described above, the memory device 100 according to one or more embodiments may improve the threshold voltage distribution of the string select lines by simultaneously performing a program operation and a corresponding verify read operation on at least two string select lines, among a plurality of string select lines that correspond to the same cell string and are arranged in a direction perpendicular to the substrate.

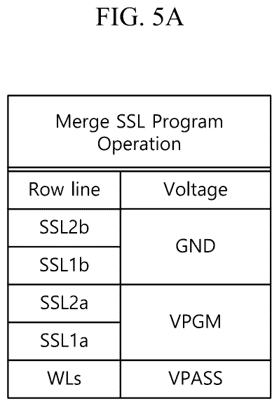

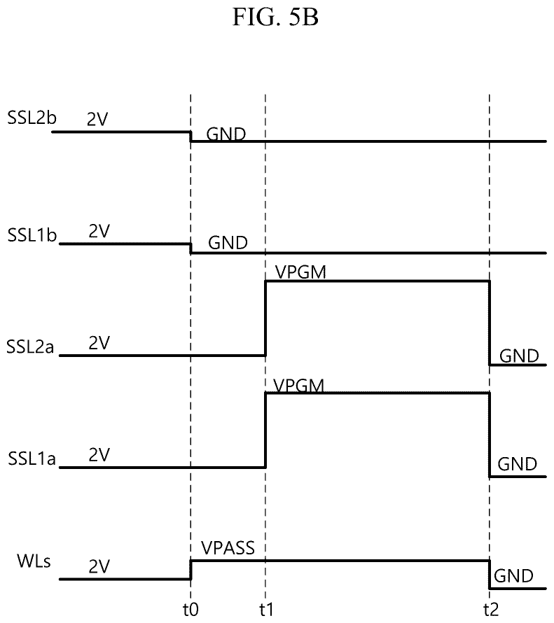

FIGS. 5A and 5B are diagrams illustrating an example of a merge program operation on a plurality of string select lines performed in the memory device of FIG. 1 according to one or more embodiments. FIG. 5A is a diagram illustrating bias conditions applied to the string select lines and wordlines according to one or more embodiments, and FIG. 5B is a timing diagram for a program operation according to one or more embodiments. For clarity, a merge program operation on the string select lines SSL2a and SSL1a will be described with reference to FIGS. 5A and 5B.

Referring to FIGS. 2, 5A, and 5B, at a time t0, a ground voltage GND may be applied to the unselected string select lines SSL2b and SSL1b. In addition, a pass voltage VPASS may be applied to the wordlines WLs.

At a time t1, a program voltage VPGM may be applied to the string select lines SSL2a and SSL1a. For example, the same level of program voltage VPGM may be applied substantially simultaneously to the selected two string select lines SSL2a and SSL1a.

During a period from the time t1 to a time t2, the ground voltage GND may continue to be applied to the unselected string select lines SSL2b and SSL1b, the pass voltage VPASS may continue to be applied to the wordlines WLs, and the program voltage VPGM may continue to be applied to the selected string select lines SSL2a and SSL1a. Accordingly, a merge program operation on the string select lines SSL2a and SSL1a may be performed.

At the time t2, the ground voltage GND may be applied to the string select lines SSL2a and SSL1a and the wordlines WLs. Accordingly, the merge program operation may be terminated.

When the number of string select lines corresponding to a single cell string is three or more and a partial merge program operation is performed on a portion of the corresponding string select lines, the pass voltage VPASS may be applied to the remaining string select lines during a period from the time t0 to the time t2.

As described above, the same program voltage is applied substantially simultaneously to the string select lines SSL2a and SSL1a, so that the string select transistors SST2a and SST1a may be programmed as a single merge string select transistor MSSTa. As a result, lateral spreading may be improved and the threshold voltage distribution of the string select lines may also be improved.

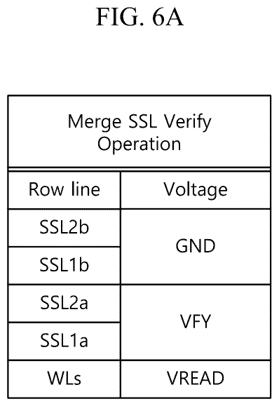

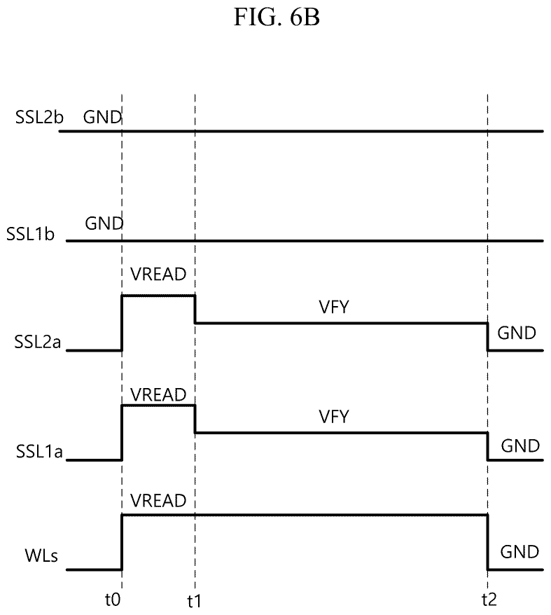

FIGS. 6A and 6B are diagrams illustrating an example of a merge verify read operation on a plurality of string select lines performed in the memory device of FIG. 1 according to one or more embodiments. FIG. 6A is a diagram illustrating the bias conditions applied to the string select lines and wordlines according to one or more embodiments, and FIG. 6B is a timing diagram for the verify read operation according to one or more embodiments. For clarity, the merge verify read operation on the string select lines SSL2a and SSL1a will be described with reference to FIGS. 6A and 6B.

Referring to FIGS. 2, 6A, and 6B, at a time t0, a ground voltage GND may be applied to the unselected string select lines SSL2b and SSL1b. A read pass voltage VREAD may be applied to the selected string select lines SSL2a and SSL1a and the wordlines WLs.

At a time t1, a verify read voltage VFY may be applied to the selected string select lines SSL2a and SSL1a. For example, the same level of verify read voltage VFY may be applied simultaneously to the two string select lines SSL2a and SSL1a.

During a period from the time t1 to a time t2, the read pass voltage VREAD may continue to be applied to the wordlines WLs, the ground voltage GND may continue to be applied to the unselected string select lines SSL2b and SSL1b, and the verify read voltage VFY continues to be applied to the selected string select lines SSL2a and SSL1a. Accordingly, a merge verify read operation on the string select lines SSL2a and SSL1a may be performed.

At the time t2, the ground voltage GND may be applied to the string select lines SSL2a and SSL1a and the wordlines WLs. Accordingly, the merge verify read operation on the string select lines SSL2a and SSL1a may be terminated.

When the number of string select lines corresponding to a single cell string is three or more and a merge verify read operation is performed on a portion of the corresponding string select lines, the read pass voltage VREAD may be applied to the remaining string select lines during a period from the time t0 to the time t2.

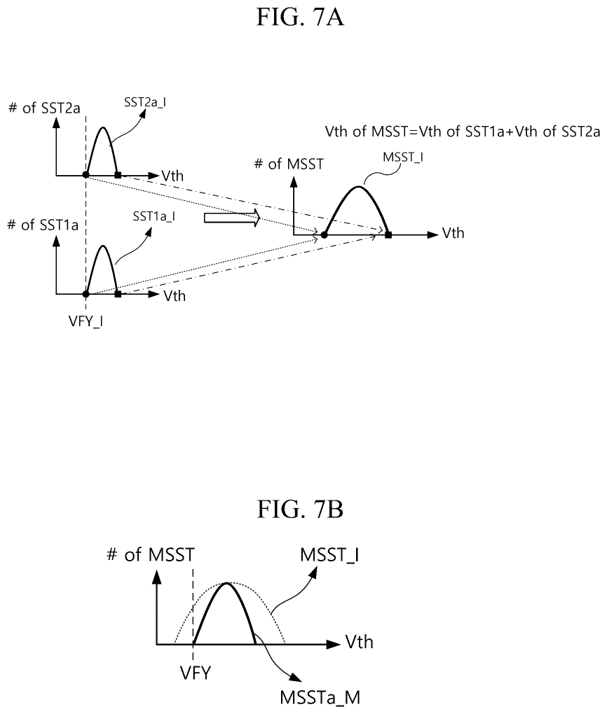

As described above, the same verify read voltage VFY is applied simultaneously to the string select lines SSL2a and SSL1a, so that the verify read operation may be performed on a single merge string select transistor MSSTa rather than on each of the string select transistors SST2a and SST1a. Accordingly, the threshold voltage distribution of the string select lines may be improved, as will be described below in FIGS. 7A and 7B.

FIGS. 7A and 7B are diagrams illustrating a distribution improvement effect when a merge program operation and a merge verify read operation are performed according to one or more embodiments. FIG. 7A is a diagram illustrating a threshold voltage distribution of string select transistors when a program operation and a verify read operation are individually performed on each of a plurality of string select lines. FIG. 7B is a diagram illustrating a threshold voltage distribution of string select transistors when a merge program operation and a merge verify read operation are performed on a plurality of string select lines according to one or more embodiments.

For clarity, an example is provided in which a program operation and a verify read operation are performed on the string select lines SSL2a and SSL1a in an arrangement structure of string select lines as illustrated in FIG. 2.

FIG. 7A illustrates a threshold voltage distribution when a program operation and a verify read operation are performed on each of the string select lines SSL2a and SSL1a. For example, a distribution SST2a_I represents a threshold voltage distribution of string select transistors connected to the string select line SSL2a, and a distribution SST1a_I represents a threshold voltage distribution of string select transistors connected to the string select line SSL1a. A voltage VFY_I represents a verify read voltage when verify read operations are individually performed on the string select line SSL2a and the string select line SSL1a.

In addition, a distribution MSST_I represents a combined threshold voltage distribution of the string select line SSL2a and the string select line SSL1a. This may be referred to as a threshold voltage distribution of the merge string select line.

Referring to the threshold voltage distribution MSST_I of the merge string select line, the lowest threshold voltage in the threshold voltage distribution SST2a_I of the string select line SSL2a and the lowest threshold voltage in the threshold voltage distribution SST1a_I of the string select line SSL1a may be reflected in the lowest threshold voltage of the threshold voltage distribution MSST_I of the merge string select line. Similarly, the highest threshold voltage in the threshold voltage distribution SST2a_I of the string select line SSL2a and the highest threshold voltage in the threshold voltage distribution SST1a_I of the string select line SSL1a may be reflected in the highest threshold voltage of the threshold voltage distribution MSST_I of the merge string select line. Accordingly, the threshold voltage distribution of the merge string select line is formed to be widely spread.

Referring to FIG. 7B, a distribution MSSTa_M represents a threshold voltage distribution when a merge program operation and a merge verify read operation are performed, and a distribution MSST_I represents a threshold voltage distribution of the merge string select line when individual program operations are performed.

As illustrated in FIG. 7B, the threshold voltage distribution of the merge string select line when a merge program operation and a merge verify read operation are performed may be formed to be narrower than the threshold voltage distribution of the merge string select line when individual program operations and individual verify read operations are performed.

This is because the merge verify read operation regards two string select transistors as a single merge string select transistor and the verify read operation is performed. For example, the distribution of the merge string select transistor is controlled through the verify read voltage VFY, so that the threshold voltage distribution of the merge string select line may be improved. Thus, a wider window margin may be secured. As a result, the overall performance of the memory device may be enhanced.

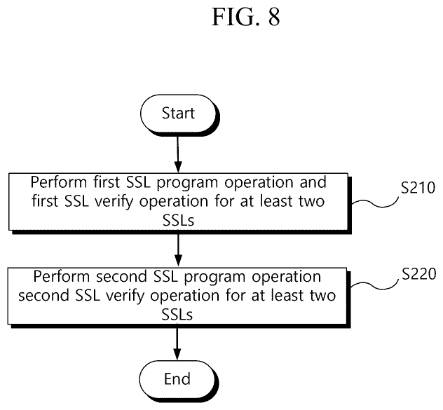

FIGS. 8, 9A to 9D, 10A and 10B are diagrams illustrating an example of a program operation and a verify read operation on a plurality of string select lines performed in the memory device of FIG. 1 according to one or more embodiments. FIGS. 8, 9A to 9D, 10A and 10B illustrate an example in which an individual program operation and an individual verify read operation are performed on each of a plurality of string select lines, and a merge program operation and a merge verify read operation are then performed on the plurality of string select lines.

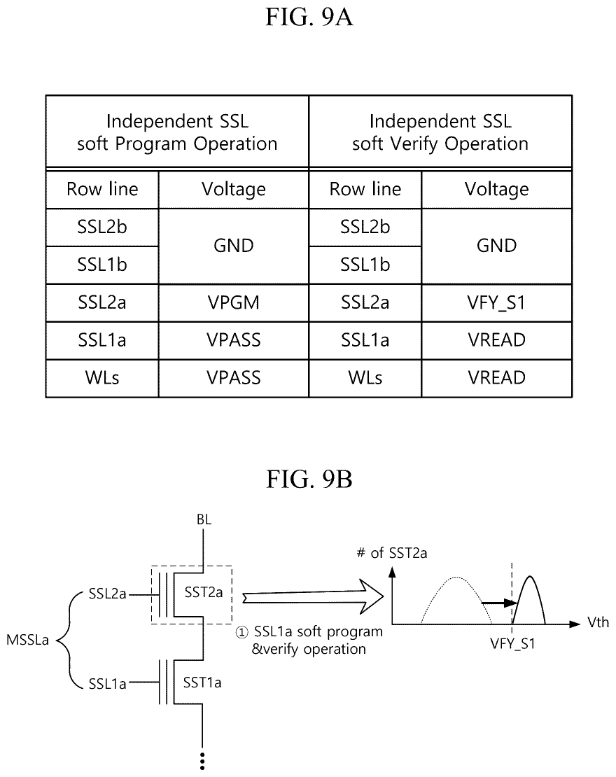

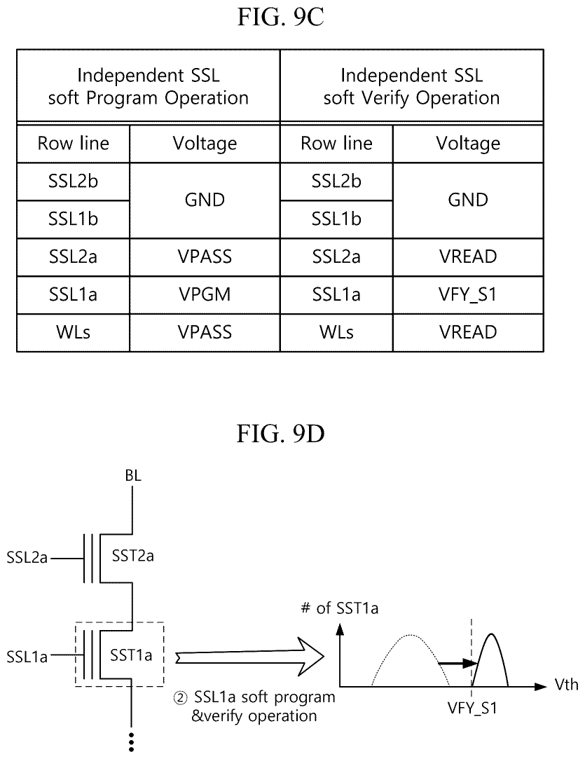

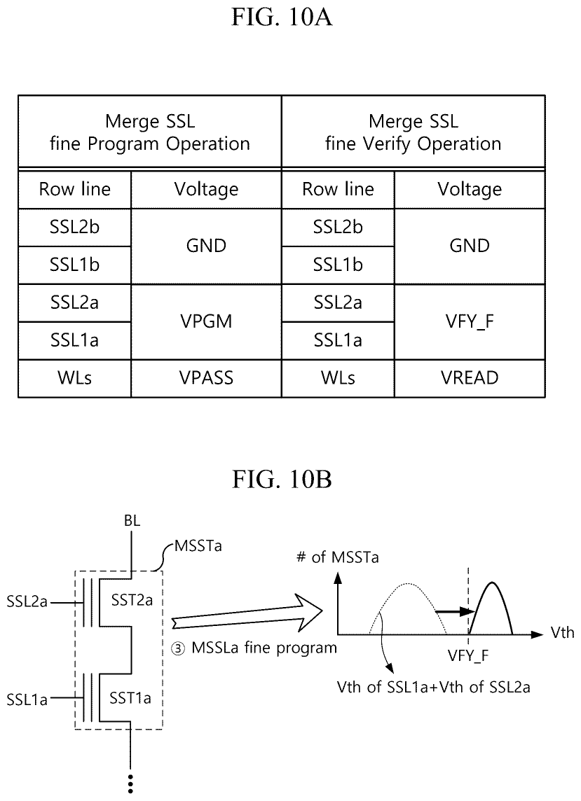

FIG. 8 is a flowchart illustrating a program operation and a verify read operation on a plurality of string select lines according to one or more embodiments. FIGS. 9A and 9C are diagrams illustrating bias conditions applied to the string select lines and wordlines during a first program operation and a first verify read operation according to one or more embodiments. FIGS. 9B and 9D illustrate changes in distribution during the first program operation and the first verify read operation according to one or more embodiments. FIG. 10A illustrates bias conditions applied to the string select lines and wordlines during a second program operation and a second verify read operation according to one or more embodiments, and FIG. 10B illustrates changes in distribution during the second program operation and the second verify read operation according to one or more embodiments.

Referring first to FIG. 8, in operation S210, a first program operation and a first verify read operation on at least two string select lines may be performed individually. The first program operation may be referred to as a soft program operation, and the first verify read operation may be referred to as a soft verify read operation.

For example, referring to FIGS. 9A and 9B, a string select line SSL2a may be selected as a target string select line on which the first program operation is to be performed. A program voltage VPGM may be applied to the selected string select line SSL2a. A pass voltage VPASS may be applied to an unselected string select line SSL1a and wordlines WLs. In addition, a ground voltage GND may be applied to the unselected string select lines SSL2b and SSL1b (see FIG. 2) spaced apart from the string select lines SSL2a and SSL1a in the Y-axis direction.

Then, a first verify read operation may be performed on the string select line SSL2a. Referring to FIGS. 9A and 9B, a verify read voltage VFY_S1 may be applied to the string select line SSL2a, a target of the verify read operation. A read pass voltage VREAD may be applied to the string select line SSL1a and the wordlines WLs, and the ground voltage GND may be applied to the string select lines SSL2b and SSL1b.

The program operation and the verify read operation are individually performed on the string select line SSL2a, so that the threshold voltage distribution of the string select transistors connected to the string select line SSL2a may be changed to be narrow, as illustrated in FIG. 9B.

Referring to FIGS. 9C and 9D, the string select line SSL1a may be selected as a target string select line for the first program operation. A program voltage VPGM may be applied to the selected string select line SSL1a. A pass voltage VPASS may be applied to the unselected string select line SSL2a and the wordlines WLs. In addition, the ground voltage GND may be applied to the unselected string select lines SSL2b and SSL1b.

Then, a first verify read operation may be performed on the string select line SSL1a. Referring to FIGS. 9C and 9D, a verify read voltage VFY_S1 may be applied to the string select line SSL1a, a target of the verify read operation. A read pass voltage VREAD may be applied to the string select line SSL2a and the wordlines WLs, and the ground voltage GND may be applied to the string select lines SSL2b and SSL1b.

The program operation and the verify read operation are individually performed on the string select line SSL1a, so that the threshold voltage distribution of the string select transistors connected to the string select line SSL1a may be changed to be narrow, as illustrated in FIG. 9D.

When it is determined that the first program operation has been completed based on a result of the first verify read operation on the first program operation, the flow proceeds to operation S220.

Returning to FIG. 8, in operation S220, a second program operation and a second verify read operation may be performed on the at least two string select lines. The second program operation may be referred to as a fine program operation, and the second verify read operation may be referred to as a fine verify read operation. In certain embodiments, the second program operation may be performed simultaneously on the at least two string select lines, and the second verify read operation may be performed simultaneously on the at least two string select lines.

For example, referring to FIGS. 10A and 10B, the string select lines SSL2a and SSL1a, which have undergone a program operation, may be selected as target lines for a merge program operation. A program voltage VPGM may be applied substantially simultaneously to the selected string select lines SSL2a and SSL1a. A pass voltage VPASS may be applied to the wordlines WLs, and the ground voltage GND may be applied to the string select lines SSL2b and SSL1b. The program voltage of the second program operation may be higher than the program voltage of the first program operation.

Then, a second verify read operation may be performed on the string select lines SSL2a and SSL1a. Referring to FIGS. 10A and 10B, the string select lines SSL2a and SSL1a targeted for the verify read operation may be selected. A verify read voltage VFY_F may be applied substantially simultaneously to the selected string select lines SSL2a and SSL1a. A read pass voltage VREAD may be applied to the wordlines WLs, and the ground voltage GND may be applied to the string select lines SSL2b and SSL1b. The verify read voltage of the second verify read operation may be higher than the verify read voltage of the first verify read operation.

Referring to FIG. 10B, a threshold voltage distribution when combining the threshold voltage distribution of the string select transistors connected to the string select line SSL2a and the threshold voltage distribution of the string select transistors connected to the string select line SSL1a is illustrated as a dashed line. In addition, the threshold voltage distribution when a merge program operation and a merge verify read operation are performed on the string select lines SSL2a and SSL1a is illustrated as a solid line. The merge program operation and the merge verify read operation are performed, so that the threshold voltage distribution of the string select transistors connected to the string select lines SSL2a and SSL1a may be changed to be narrow, as illustrated in FIG. 10B.

As a result, referring to FIGS. 9B, 9D, and 10B, the first program operation and the first verify read operation may narrow the threshold voltage distribution corresponding to individual string select lines. Then, the second program operation, which is a merge program operation, and the second verify read operation, which is a merge verify read operation, may further narrow the threshold voltage distribution corresponding to the merge string select lines.

As described above, in certain embodiments, an individual program operation may be performed on each of a plurality of string select lines, and then a merge program operation may be performed. Accordingly, the threshold voltage distribution of the string select lines may be further improved and lateral spreading may also be improved. For example, compared to performing only individual program operations or only merge program operations, the improvement in the threshold voltage distribution of the string select lines may be greater.

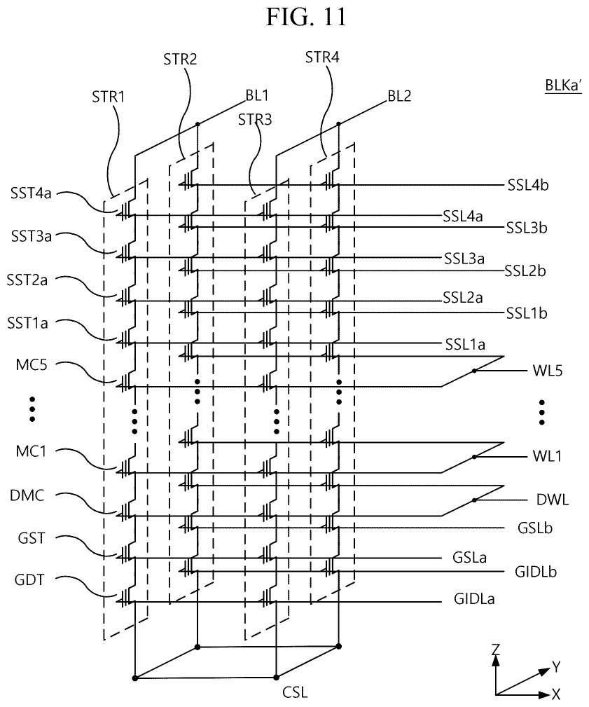

FIG. 11 is a circuit diagram of a single memory block, among a plurality of memory blocks included in the memory cell array of FIG. 1. A memory block BLKa′ of FIG. 11 is similar to the memory block BLKa of FIG. 2. Therefore, the same or similar components are represented by the same reference numerals, and redundant descriptions will be omitted to avoid repetition.

Unlike the illustration in FIG. 2, FIG. 11 illustrates cell strings STR1 to STR4, each including four string select transistors. The cell string STR1 includes four string select transistors SST4a, SST3a, SST2a, and SST1a. Based on a single cell string, each of the plurality of string select transistors may be connected to a corresponding string select line among a plurality of string select lines. For example, a gate of the string select transistor SST4a may be connected to the string select line SSL4a, a gate of the string select transistor SST3a may be connected to the string select line SSL3a, a gate of the string select transistor SST2a may be connected to the string select line SSL2a, and a gate of the string select transistor SST1a may be connected to the string select line SSL1a.

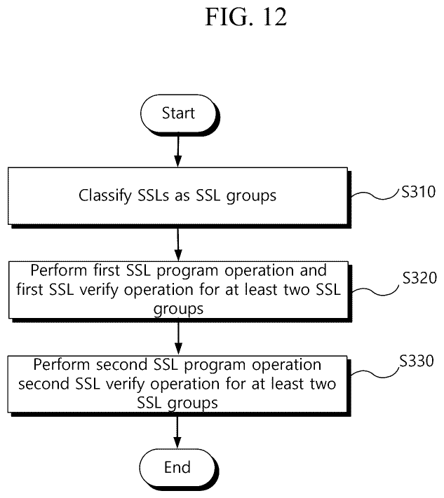

FIG. 12 is a diagram illustrating an example of a program operation and a verify read operation on a plurality of string select lines performed by the memory device of FIG. 1 according to one or more embodiments. Hereinafter, the program operation and the verify read operation on the plurality of string select lines will be described with reference to FIGS. 11 and 12.

In operation S310, a plurality of string select lines may be classified into one or more string select line groups (hereinafter, referred to as “SSL groups”).

In certain embodiments, the number of string select lines may be equal to the number of SSL groups. For example, the four string select lines SSL4a, SSL3a, SSL2a, and SSL1a in FIG. 11 may correspond to four SSL groups, respectively.

In certain embodiments, the number of string select lines may be greater than the number of SSL groups. Referring to FIG. 11, the four string select lines SSL4a, SSL3a, SSL2a, and SSL1a may be classified into two SSL groups. For example, the string select lines SSL4a and SSL3a may correspond to a first SSL group, and the string select lines SSL2a and SSL1a may correspond to a second SSL group. Alternatively, the string select lines SSL4a, SSL3a, and SSL2a may correspond to a first SSL group, and the string select line SSL1a may correspond to a second SSL group.

Referring to FIG. 11, the four string select lines SSL4a, SSL3a, SSL2a, and SSL1a may be classified into three SSL groups. For example, the string select line SSL4a may correspond to a first SSL group, the string select lines SSL3a and SSL2a may correspond to a second SSL group, and the string select line SSL1a may correspond to a third SSL group.

The above examples describe cases in which adjacent string select lines are classified into the same group, but embodiments are not limited thereto. For example, non-adjacent string select lines may be classified into the same group.

In operation S320, a first program operation and a first verify read operation may be individually performed on each SSL group. The first program operation may be referred to as a soft program operation, and the first verify read operation may be referred to as a soft verify read operation.

Referring to FIGS. 1 and 11, the peripheral circuit 120 may sequentially perform program operations on the respective SSL groups. The program operation may be sequentially performed on the at least one SST group in the order of decreasing a vertical distance from the substrate, but embodiments are not limited thereto.

When the number of string select lines corresponding to a single SSL group is two or more, the program operation and the verify read operation may be performed simultaneously on the plurality of string select lines within the single SSL group. For example, in terms of the entire group, an individual program operation and an individual verify read operation may be performed on each group. However, a merge program operation and a merge verify read operation may be performed in a plurality of string select lines within a group. In certain embodiments, a verify read voltage on an SSL group corresponding to a plurality of string select lines may be higher than a verify read voltage on an SSL group corresponding to a single string select line.

Referring to FIG. 11, when the four string select lines SSL4a, SSL3a, SSL2a, and SSL1a correspond to four SSL groups, a program operation and a verify read operation may be performed sequentially on each of the first to fourth SSL groups.

For example, when the string select lines SSL4a and SSL3a correspond to a first SSL group and the string select lines SSL2a and SSL1a correspond to a second SSL group, the program operation and verify read operation may be performed sequentially for each of the first and second SSL groups. A merge program operation and a merge verify read operation may be performed on the plurality of select lines included in a single SSL group. For example, the string select lines SSL4a and SSL3a may be programmed simultaneously, and then the string select lines SSL2a and SSL1a may be programmed simultaneously.

For example, when the string select line SSL4a corresponds to a first SSL group, the string select lines SSL3a and SSL2a correspond to a second SSL group, and the string select line SSL1a corresponds to a third SSL group, the program operation and verify read operation may be performed sequentially for each of the first to third SSL groups. A merge program operation and a merge verify read operation may be performed on the second SSL group. For example, the string select lines SSL3a and SSL2a may be programmed simultaneously after programming the string select line SSL4a, and then the string select line SSL1a may be programmed. The verify read voltage for the second SSL group may be higher than the verify read voltage for the first and third SSL groups.

In certain embodiments, when all of the plurality of string select lines are classified into a single group, a program operation and a verify read operation may be performed simultaneously on all of the plurality of string select lines. For example, when the four string select lines SSL4a, SSL3a, SSL2a, and SSL1a correspond to a single SSL group, the program operation and verify read operation may be performed simultaneously on each of the four string select lines SSL4a, SSL3a, SSL2a, and SSL1a.

When it is determined that the first program operation has been completed based on a result of the first verify read operation on the first program operation, the flow proceeds to operation S330.

In operation S330, a second program operation and a second verify read operation may be performed on the SSL groups. The second program operation may be referred to as a fine program operation, and the second verify read operation may be referred to as a fine verify read operation. A program voltage for the second program operation may be higher than a program voltage for the first program operation. A verify read voltage for the second verify read operation may be higher than a verify read voltage for the first verify read operation.

In certain embodiments, the second program operation on all of the SSL groups may be performed simultaneously. For example, a program voltage may be applied simultaneously to the string select lines corresponding to all of the SSL groups. However, embodiments are not limited thereto. For example, the second program operation on a portion of the SSL groups may be performed simultaneously.

In certain embodiments, the second verify read operation on all of the SSL groups may be performed simultaneously. For example, a verify read voltage may be applied simultaneously to the string select lines corresponding to all of the SSL groups. However, embodiments are not limited thereto. For example, the second verify read operation on a portion of the SSL groups may be performed simultaneously. The more SSL groups, for example, the more corresponding string select lines on which the verify read operation is performed simultaneously, the higher the verify read voltage of the second verify read operation may be.

As described above, in certain embodiments, an individual program operation/individual verify read operation or a partial merge program operation/partial merge verify read operation may be performed on a plurality of string select lines, and then a merge program operation/merge verify read operation or a partial merge program operation/partial merge verify read operation may be performed. Accordingly, various bias combinations applied during the string select line program operation and verify read operation may be used based on design requirements of the memory device, and the threshold voltage distribution and lateral spreading of the string select lines may be further improved.

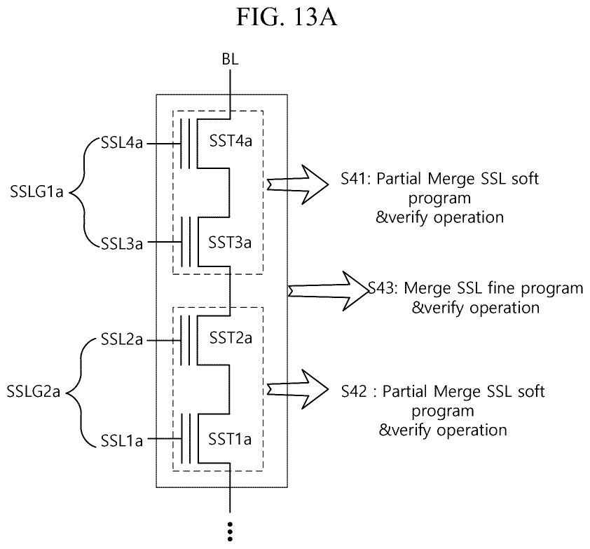

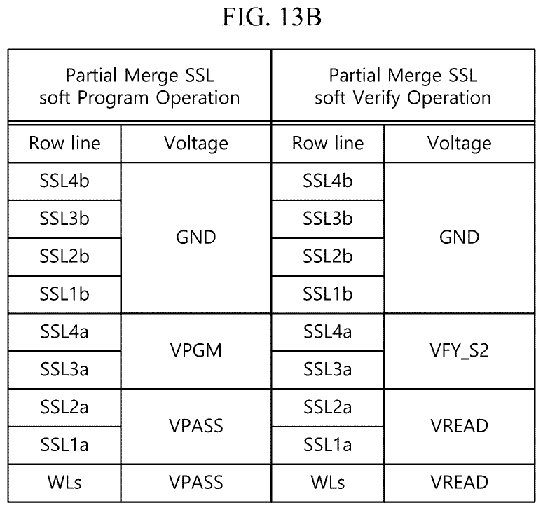

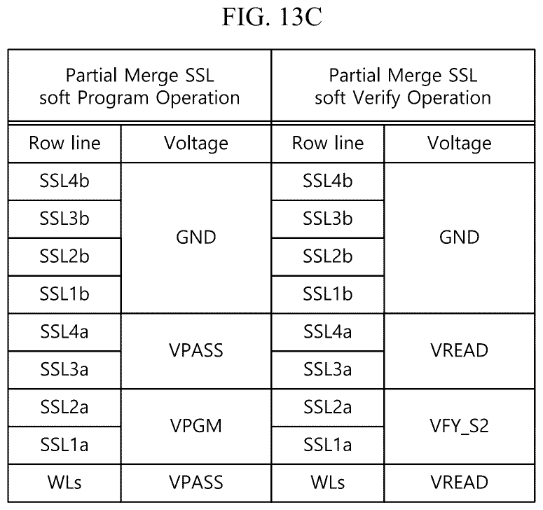

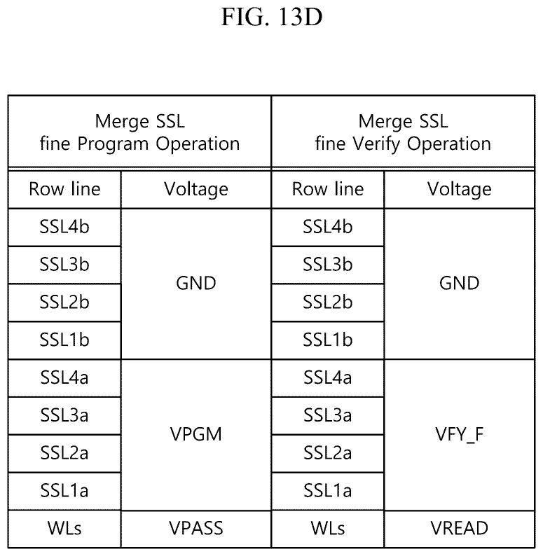

FIG. 13A is a diagram illustrating an example of a program operation and a verify read operation on a plurality of string select lines according to FIG. 12 according to one or more embodiments. FIGS. 13B and 13C are diagram illustrating bias conditions applied to string select lines and wordlines during a first program operation and a first verify read operation according to one or more embodiments. FIG. 13D are a diagram illustrating bias conditions applied to string select lines and wordlines during a second program operation and a second verify read operation according to one or more embodiments.

Referring to FIG. 13A, the string select lines SSL4a and SSL3a correspond to a first SSL group SSLG1a, and the string select lines SSL2a and SSL1a correspond to a second SSL group SSLG2a.

A first program operation and a first verify read operation may be performed sequentially on each of the first SSL group SSLG1a and the second SSL group SSLG2a. A merge program operation and a merge verify read operation may be performed on the plurality of string select lines included in the same group.

In operation S41, a first program operation and a first verify read operation may be performed on the first SSL group SSLG1a.

A first program operation may be performed on the first SSL group SSLG1a. Referring to FIG. 13B, a program voltage VPGM may be applied to the string select lines SSL4a and SSL3a targeted for the program operation. A pass voltage VPASS may be applied to the string select lines SSL2a and SSL1a and the wordlines WLs, and the ground voltage GND may be applied to the string select lines SSL4b, SSL3b, SSL2b, and SSL1b (see FIG. 11) spaced apart from the string select lines SSL4a, SSL3a, SSL2a, and SSL1a in a bitline direction (a Y-axis direction). The ground voltage GND may be 0V.

Then, a first verify read operation may be performed on the first SSL group SSLG1a. Referring to FIG. 13B, a verify read voltage VFY_S2 may be applied to the string select lines SSL4a and SSL3a targeted for the verify read operation. A read pass voltage VREAD may be applied to the string select lines SSL2a and SSL1a and the wordlines WLs, and the ground voltage GND may be applied to the string select lines SSL4b, SSL3b, SSL2b, and SSL1b (see FIG. 11).

In operation S42, a first program operation and a first verify read operation may be performed on the second SSL group SSLG2a.

A first program operation may be performed on the second SSL group SSLG2a. Referring to FIG. 13C, a program voltage VPGM may be applied to the string select lines SSL2a and SSL1a targeted for the program operation. A pass voltage VPASS may be applied to the string select lines SSL4a and SSL3a and the wordlines WLs, and the ground voltage GND may be applied to the string select lines SSL4b, SSL3b, SSL2b, and SSL1b (see FIG. 11).

Then, a first verify read operation may be performed on the second SSL group SSLG2a. Referring to FIG. 13C, a verify read voltage VFY_S2 may be applied to the string select lines SSL2a and SSL1a targeted for the verify read operation. A read pass voltage VREAD may be applied to the string select lines SSL4a and SSL3a and the wordlines WLs, and the ground voltage GND may be applied to the string select lines SSL4b, SSL3b, SSL2b, and SSL1b (see FIG. 11).

In certain embodiments, program voltages for the first program operation on the first SSL group SSLG1a and the second SSL group SSLG2a may be the same. In certain embodiments, verify read voltages for the first verify read operation on the first SSL group SSLG1a and the second SSL group SSLG2a may be the same.

In operation S43, a second program operation and a second verify read operation may be performed on the first SSL group SSLG1a and the second SSL group SSLG2a. The program voltage of the second program operation may be higher than the program voltage of the first program operation. The verify read voltage of the second verify read operation may be higher than the verify read voltage of the first verify read operation.

A second program operation may be performed on the first SSL group SSLG1a and the second SSL group SSLG2a. Referring to FIG. 13D, a program voltage VPGM may be applied to the string select lines SSL4a, SSL3a, SSL2a, and SSL1a targeted for programming. A pass voltage VPASS may be applied to the wordlines WLs, and the ground voltage GND may be applied to the string select lines SSL4b, SSL3b, SSL2b, and SSL1b (see FIG. 11).

Then, a second verify read operation may be performed on the first SSL group SSLG1a and the second SSL group SSLG2a. Referring to FIG. 13D, a verify read voltage VFY_F may be applied to the string select lines SSL4a, SSL3a, SSL2a, and SSL1a targeted for the verify read operation. A read pass voltage VREAD may be applied to the wordlines WLs, and the ground voltage GND may be applied to the string select lines SSL4b, SSL3b, SSL2b, and SSL1b (see FIG. 11).

In certain embodiments, the program voltages for the second program operation on the first SSL group SSLG1a and the second SSL group SSLG2a may be the same, and threshold voltages of the string select transistors corresponding to the first SSL group SSLG1a and the second SSL group SSLG2a after the completion of the second program operation may be the same. In certain embodiments, the verify read voltages for the second verify read operation on the first SSL group SSLG1a and the second SSL group SSLG2a may be the same. In FIG. 13A, the second program operation and the second verify read operation on the first SSL group SSLG1a and the second SSL group SSLG2a are illustrated as being performed simultaneously, but embodiments are not limited thereto. For example, the second program operation and the second verify read operation may be performed individually for each group, similarly to the first program operation and the first verify read operation.

As described above, in certain embodiments, a partial merge program operation/partial merge verify read operation may be performed on a plurality of string select lines, and then a merge program operation/merge verify read operation may be performed. Accordingly, the threshold voltage distribution and lateral spreading of the string select lines may be improved.

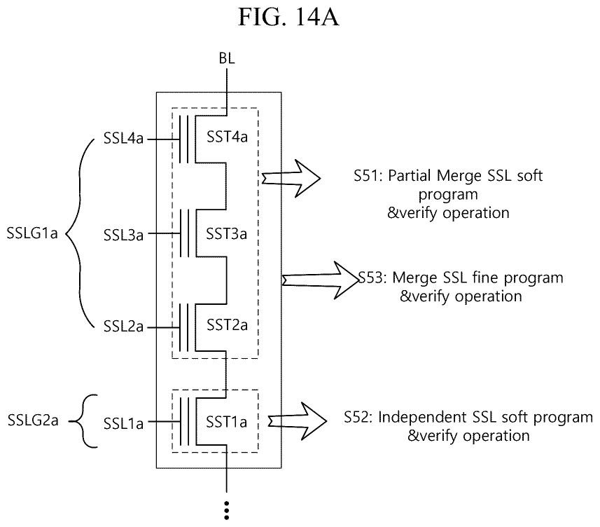

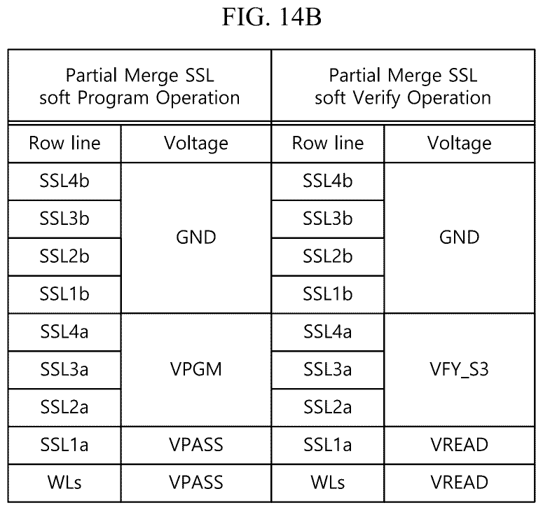

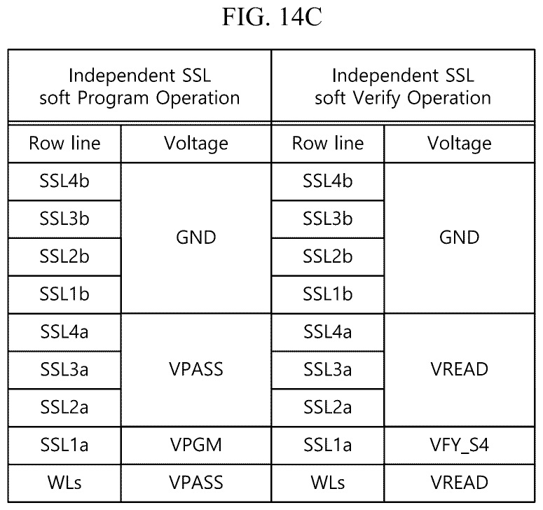

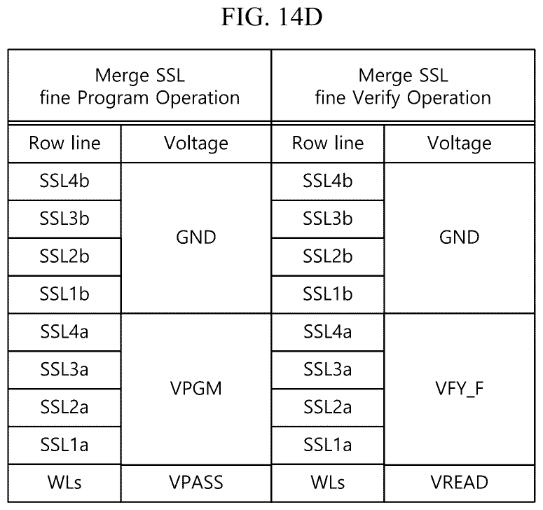

FIG. 14A is a diagram illustrating an example of a program operation and a verify read operation on a plurality of string select lines according to FIG. 12 according to one or more embodiments. FIGS. 14B and 14C are diagrams illustrating bias conditions applied to string select lines and wordlines during a first program operation and a first verify read operation according to one or more embodiments. FIG. 14D is a diagram illustrating bias conditions applied to string select lines and wordlines during a second program operation and a second verify read operation according to one or more embodiments.

Referring to FIG. 14A, the string select lines SSL4a, SSL3a, and SSL2a may correspond to a first SSL group SSLG1a, and the string select line SSL1a may correspond to a second SSL group SSLG2a.

A first program operation and a first verify read operation may be performed sequentially on each of the first SSL group SSLG1a and the second SSL group SSLG2a. A merge program operation and a merge verify read operation may be performed on the plurality of string select lines included in the same SSL group. For example, a merge program operation and a merge verify read operation may be performed on the plurality of string select lines SSL4a, SSL3a, and SSL2a included in the first SSL group SSLG1a.

In operation S51, a first program operation and a first verify read operation may be performed on the first SSL group SSLG1a.

A first program operation may be performed on the first SSL group SSLG1a. Referring to FIG. 14B, a program voltage VPGM may be applied to the string select lines SSL4a, SSL3a, and SSL2a targeted for the program operation. A pass voltage VPASS may be applied to the string select line SSL1a and the wordlines WLs, and the ground voltage GND may be applied to the string select lines SSL4b, SSL3b, SSL2b, and SSL1b (see FIG. 11) that are spaced apart from the string select lines SSL4a, SSL3a, SSL2a, and SSL1a in a bitline direction (a Y-axis direction). The ground voltage GND may be 0V.

Then, a first verify read operation may be performed on the first SSL group SSLG1a. Referring to FIG. 14B, a verify read voltage VFY_S3 may be applied to the string select lines SSL4a, SSL3a, and SSL2a targeted for the verify read operation. A read pass voltage VREAD may be applied to the string select line SSL1a and the wordlines WLs, and the ground voltage GND may be applied to the string select lines SSL4b, SSL3b, SSL2b, and SSL1b.

In operation S52, a first program operation and a first verify read operation may be performed on the second SSL group SSLG2a.

A first program operation may be performed on the second SSL group SSLG2a. Referring to FIG. 14C, a program voltage VPGM may be applied to the string select line SSL1a targeted for the program operation. A pass voltage VPASS may be applied to the string select lines SSL4a, SSL3a, and SSL2a and the wordlines WLs, and the ground voltage GND may be applied to the string select lines SSL4b, SSL3b, SSL2b, and SSL1b.

Then, a first verify read operation may be performed on the second SSL group SSLG2a. Referring to FIG. 14C, a verify read voltage VFY_S4 may be applied to the string select line SSL1a targeted for the verify read operation. A read pass voltage VREAD may be applied to the string select lines SSL4a, SSL3a, and SSL2a and the wordlines WLs, and the ground voltage GND may be applied to the string select lines SSL4b, SSL3b, SSL2b, and SSL1b.

In certain embodiments, program voltages for the first program operation on the first SSL group SSLG1a and the second SSL group SSLG2a may be the same. In certain embodiments, verify read voltages for the first verify read operation on the first SSL group SSLG1a and the second SSL group SSLG2a may be different. For example, the verify read voltage VFY_S3 for the first verify read operation on the first SSL group SSLG1a, which corresponds to a plurality of string select lines, may be higher than the verify read voltage VFY_S4 for the first verify read operation on the second SSL group SSLG2a, which corresponds to a single string select line.

In operation S53, a second program operation and a second verify read operation may be performed on the first SSL group SSLG1a and the second SSL group SSLG2a. A program voltage for the second program operation may be higher than a program voltage for the first program operation. A verify read voltage for the second verify read operation may be higher than a verify read voltage for the first verify read operation.

A second program operation may be performed simultaneously on the first SSL group SSLG1a and the second SSL group SSLG2a. Referring to FIG. 14D, a program voltage VPGM may be applied to the string select lines SSL4a, SSL3a, SSL2a, and SSL1a targeted for the program operation. A pass voltage VPASS may be applied to the wordlines WLs, and the ground voltage GND may be applied to the string select lines SSL4b, SSL3b, SSL2b, and SSL1b.

Then, a second verify read operation may be performed simultaneously for the first SSL group SSLG1a and the second SSL group SSLG2a. Referring to FIG. 14D, a verify read voltage VFY_F may be applied to the string select lines SSL4a, SSL3a, SSL2a, and SSL1a targeted for the verify read operation. A read pass voltage VREAD may be applied to the wordlines WLs, and the ground voltage GND may be applied to the string select lines SSL4b, SSL3b, SSL2b, and SSL1b.

In certain embodiments, program voltages for the second program operation on the first SSL group SSLG1a and the second SSL group SSLG2a may be the same. In certain embodiments, verify read voltages for the second verify read operation on the first SSL group SSLG1a and the second SSL group SSLG2a may be the same. In FIG. 14A, the second program operation and the second verify read operation on the first SSL group SSLG1a and the second SSL group SSLG2a are illustrated as being performed simultaneously, but embodiments are not limited thereto. For example, the second program operation and the second verify read operation may also be performed individually on each group, similarly to the first program operation and the first verify read operation.

As described above, in certain embodiments, a partial merge program operation/partial merge verify read operation may be performed on a plurality of string select lines, and then a merge program operation/merge verify read operation may be performed. Accordingly, the threshold voltage distribution and lateral spreading of the string select lines may be improved.

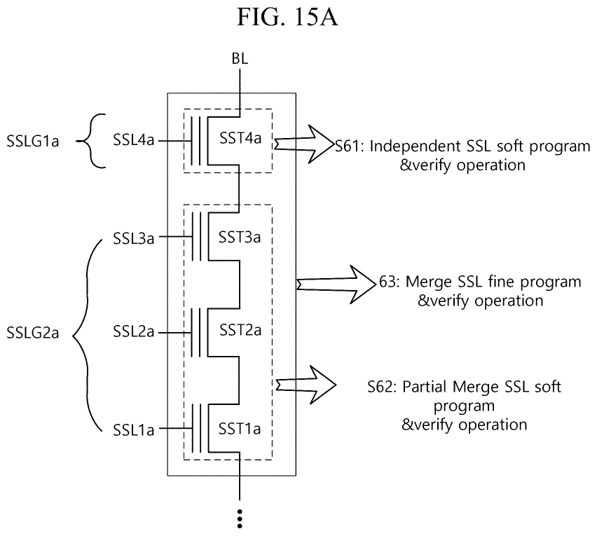

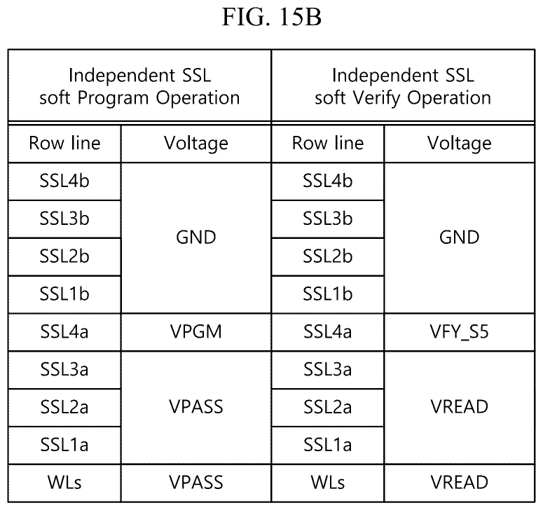

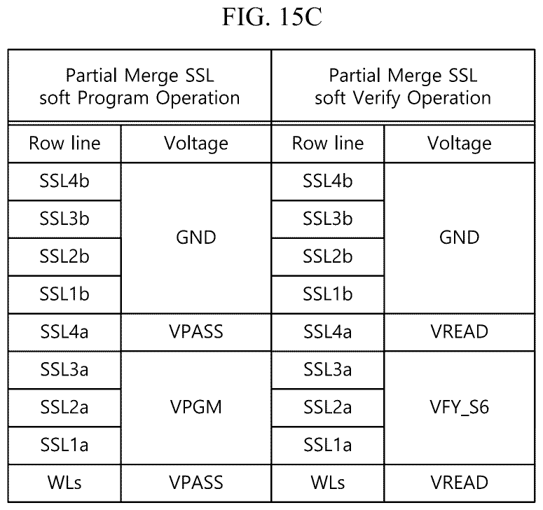

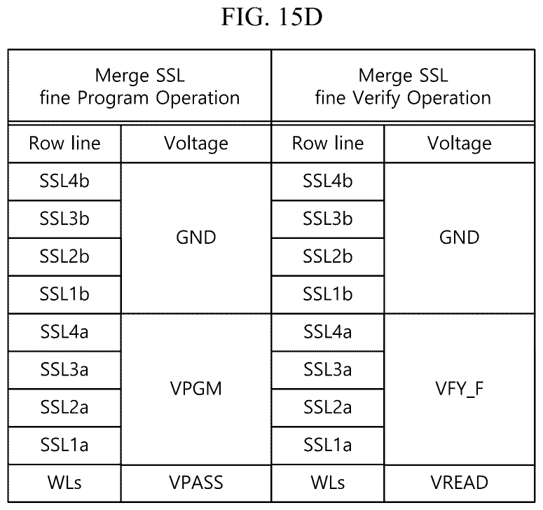

FIG. 15A is a diagram illustrating an example of a program operation and a verify read operation on a plurality of string select lines according to FIG. 12 according to one or more embodiments. FIGS. 15B and 15C are diagrams illustrating bias conditions applied to string select lines and wordlines during a first program operation and a first verify read operation according to one or more embodiments. FIG. 15D is a diagram illustrating bias conditions applied to string select lines and wordlines during a second program operation and a second verify read operation according to one or more embodiments.

Referring to FIG. 15A, a string select line SSL4a may correspond to a first SSL group SSLG1a, and the string select lines SSL3a, SSL2a, and SSL1a may correspond to a second SSL group SSLG2a.

A first program operation and a first verify read operation may be sequentially performed on each of the first SSL group SSLG1a and the second SSL group SSLG2a. A merge program operation and a merge verify read operation may be performed on a plurality of string select lines included in the same SSL group. For example, a merge program operation and a merge verify read operation may be performed on the plurality of string select lines SSL3a, SSL2a, and SSL1a included in the second SSL group SSLG2a.

In operation S61, a first program operation and a first verify read operation on the first SSL group SSLG1a may be performed.

A first program operation on the first SSL group SSLG1a may be performed. Referring to FIG. 15B, a program voltage VPGM may be applied to the string select line SSL4a targeted for the program operation. A pass voltage VPASS may be applied to the string select lines SSL3a, SSL2a, and SSL1a and the wordlines WLs, and the ground voltage GND may be applied to the string select lines SSL4b, SSL3b, SSL2b, and SSL1b (see FIG. 11) spaced apart in a bitline direction from the string select lines SSL4a, SSL3a, SSL2a, and SSL1a. The ground voltage GND may be 0V.

Then, a first verify read operation on the first SSL group SSLG1a may be performed. Referring to FIG. 15B, a verify read voltage VFY_S5 may be applied to the string select line SSL4a targeted for the verify read operation. A read pass voltage VREAD may be applied to the string select lines SSL3a, SSL2a, and SSL1a and the wordlines WLs, and the ground voltage GND may be applied to the string select lines SSL4b, SSL3b, SSL2b, and SSL1b (see FIG. 11).

In operation S62, a first program operation and a first verify read operation on the second SSL group SSLG2a may be performed.

A first program operation on the second SSL group SSLG2a may be performed. Referring to FIG. 15C, a program voltage VPGM may be applied to the string select lines SSL3a, SSL2a, and SSL1a targeted for the program operation. A pass voltage VPASS may be applied to the string select line SSL4a and the wordlines WLs, and the ground voltage GND may be applied to the string select lines SSL4b, SSL3b, SSL2b, and SSL1b (see FIG. 11).

Then, a first verify read operation on the second SSL group SSLG2a may be performed. Referring to FIG. 15C, a verify read voltage VFY_S6 may be applied to the string select lines SSL3a, SSL2a, and SSL1a targeted for the verify read operation. A read pass voltage VREAD may be applied to the string select line SSL4a and the wordlines WLs, and the ground voltage GND may be applied to the string select lines SSL4b, SSL3b, SSL2b, and SSL1b (see FIG. 11).

In certain embodiments, program voltages during the first program operation on the first SSL group SSLG1a and the second SSL group SSLG2a may be the same. In certain embodiments, verify read voltages during the first verify read operation on the first SSL group SSLG1a and the second SSL group SSLG2a may be different. For example, the verify read voltage VFY_S6 during the first verify read operation on the second SSL group SSLG2a corresponding to a plurality of string select lines may be higher than the verify read voltage VFY_S5 during the first verify read operation on the first SSL group SSLG1a corresponding to a single string select line.

In operation S63, a second program operation and a second verify read operation on the first SSL group SSLG1a and the second SSL group SSLG2a may be performed. A program voltage for the second program operation may be higher than a program voltage for the first program operation. A verify read voltage for the second verify read operation may be higher than a verify read voltage for the first verify read operation.

A second program operation on the first SSL group SSLG1a and the second SSL group SSLG2a may be performed. Referring to FIG. 15D, a program voltage VPGM may be applied to the string select lines SSL4a, SSL3a, SSL2a, and SSL1a targeted for the program operation. A pass voltage VPASS may be applied to the wordlines WLs, and the ground voltage GND may be applied to the string select lines SSL4b, SSL3b, SSL2b, and SSL1b (see FIG. 11).

Then, a second verify read operation on the first SSL group SSLG1a and the second SSL group SSLG2a may be performed. Referring to FIG. 15D, a verify read voltage VFY_F may be applied to the string select lines SSL4a, SSL3a, SSL2a, and SSL1a targeted for the verify read operation. A read pass voltage VREAD may be applied to the wordlines WLs, and the ground voltage GND may be applied to the string select lines SSL4b, SSL3b, SSL2b, and SSL1b (see FIG. 11).

In certain embodiments, program voltages during the second program operation on the first SSL group SSLG1a and the second SSL group SSLG2a may be the same. In certain embodiments, verify read voltages during the second verify read operation on the first SSL group SSLG1a and the second SSL group SSLG2a may be the same. In FIG. 15A, the second program operation and the second verify read operation on the first SSL group SSLG1a and the second SSL group SSLG2a may be performed simultaneously, but embodiments are not limited thereto. For example, the second program operation and the second verify read operation may be performed individually on each group, similarly to the first program operation and the first verify read operation.

As described above, in certain embodiments, a partial merge program operation/partial merge verify read operation may be performed on a plurality of string select lines, and then a merge program operation/merge verify read operation may be performed. Accordingly, the threshold voltage distribution and lateral spreading of the string select lines may be improved.

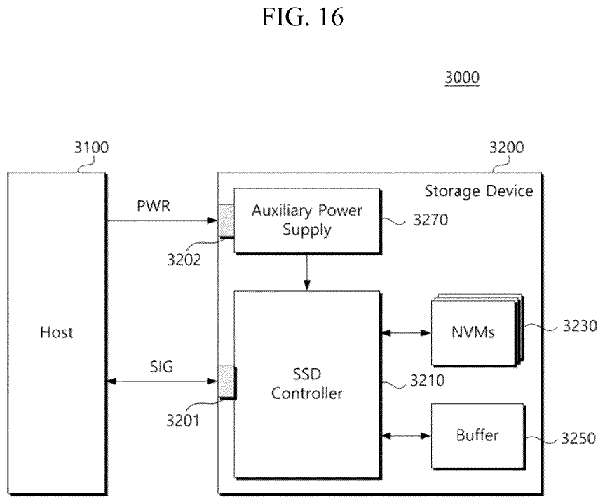

FIG. 16 is a block diagram of a storage system according to one or more embodiments.

Referring to FIG. 16, the storage system 3000 may include a host 3100 and a storage device 3200 implemented as a solid-state drive (SSD). The storage device 3200 may include a plurality of non-volatile memory devices 3230.

In certain embodiments, the plurality of non-volatile memory devices 3230 may include the memory device described with reference to FIGS. 1 to 4, 5A, 5B, 6A, 6B, 7B, 8, 9A to 9D, 10A, 10B, 11, 12, 13A to 13D, 14A to 14D, and 15A to 15D. The storage device 3200 may exchange signals SIG with the host 3100 through a signal connector 3201 and receives power PWR through a power connector 3202. The storage device 3200 may include an SSD controller 3210, the plurality of non-volatile memory devices 3230, a buffer memory 3240, and an auxiliary power supply 3270. The SSD controller 3210 may control the plurality of non-volatile memory devices 3230 in response to the signals SIG received from the host 3100. The plurality of non-volatile memory devices 3230 may operate under the control of the SSD controller 3210. The auxiliary power supply 3270 may be connected to the host 3100 through the power connector 3202. The auxiliary power supply 3270 may receive and charge power PWR from the host 3100. The auxiliary power supply 3270 may provide power to the storage device 3200 when the power supply from the host 3100 is unstable. The buffer memory 3250 may be used as a buffer memory of the storage device 3200.

It will be understood that “simultaneously” may refer to “simultaneously” or “substantially simultaneously,” and should be construed as including cases in which the two string selection lines receive their respective voltage levels within an allowable timing difference caused by normal variations in driver strength, wiring resistance-capacitance (RC) delay, or load conditions, such that the circuit operates as if the voltages were applied at the same time for the intended selection operation.

In an exemplary embodiment, at least one of the plurality of nonvolatile memory devices 3230 may correspond to the same cell string and may include a plurality of string select lines disposed in a direction perpendicular to a substrate. At least one of the plurality of non-volatile memory devices 3230 may substantially simultaneously perform a program operation on at least two of the plurality of string select lines. Alternatively, at least one of the plurality of nonvolatile memory devices 3230 may substantially simultaneously perform a verify read operation on at least two of the plurality of string select lines. Accordingly, the distribution of threshold voltages of the string select lines may be improved.

As set forth above, according to one or more embodiments, a memory device may improve a threshold voltage distribution of string select lines.

While various embodiments have been shown and described above, it will be apparent to those skilled in the art that modifications and variations could be made without departing from the scope of the present invention as defined by the appended claims.

What is claimed is:

1. A memory device comprising:
a memory cell array including a plurality of cell strings disposed on a substrate; and
a peripheral circuit configured to perform a program operation on a plurality of string select lines corresponding to one of the plurality of cell strings and arranged in a direction perpendicular to the substrate, wherein:
the peripheral circuit is configured to simultaneously perform a program operation on at least two string select lines of the plurality of string select lines,
each of the plurality of cell strings includes a plurality of string select transistors, a plurality of memory cells, and one or more ground select transistors connected in series, and
each of the plurality of string select transistors is connected to a corresponding string select line of the plurality of string select lines.

2. The memory device of claim 1, wherein the same program voltage is simultaneously applied to the at least two string select lines when the program operation is simultaneously performed on the at least two string select lines.

3. The memory device of claim 2, wherein the same verify read voltage is simultaneously applied to the at least two string select lines during a verify read operation corresponding to the program operation.

4. The memory device of claim 2, wherein the at least two string select lines are adjacent to each other in a direction perpendicular to the substrate.

5. The memory device of claim 2, wherein the at least two string select lines are not adjacent to each other in a direction perpendicular to the substrate.

6. The memory device of claim 2, wherein:
the program operation on the plurality of string select lines comprises a first program operation and a second program operation,
the plurality of string select lines are classified into at least two string select line groups,
the program operation is individually performed on the at least two string select line groups during the first program operation, and
the program operation is simultaneously performed on the at least two string select line groups during the second program operation.

7. The memory device of claim 6, wherein a program voltage for the second program operation is higher than a program voltage for the first program operation.

8. The memory device of claim 7, wherein:
the peripheral circuit is further configured to perform a verify read operation on the plurality of string select lines,
the verify read operation comprises a first verify read operation and a second verify read operation,
the first verify read operation corresponds to the first program operation, and the second verify read operation corresponds to the second program operation,
the verify read operation is individually performed on the at least two string select line groups during the first verify read operation, and
the verify read operation is simultaneously performed on the at least two string select line groups during the second verify read operation.

9. The memory device of claim 8, wherein, during the first verify read operation:
a verify read voltage is simultaneously applied to the string select lines within the same string select line group when the number of string select lines corresponding to the same string select line group is two or more, and
the verify read voltage for a string select line group corresponding to two or more string select lines is higher than a verify read voltage for a string select line group corresponding to a single string select line.

10. The memory device of claim 6, wherein the program operation is sequentially performed on the at least two string select line groups in an order of decreasing a vertical distance from the substrate.

11. The memory device of claim 6, wherein a program voltage is simultaneously applied to the string select lines within the same string select line group during the first program operation when the number of string select lines corresponding to the same string select line group is two or more.

12. A method of operating a memory device comprising a plurality of cell strings each including a plurality of string select transistors, a plurality of memory cells, and one or more ground select transistors connected in series, each of the plurality of string select transistors connected to a corresponding string select line of a plurality of string select lines, the plurality of cell strings disposed on a substrate, the method comprising:
selecting at least two string select lines from among the plurality of string select lines corresponding to one of the plurality of cell strings and arranged in a direction perpendicular to the substrate; and
simultaneously performing a program operation on the selected at least two string select lines.

13. The method of claim 12, wherein the simultaneously performing of the program operation on the selected at least two string select lines includes simultaneously applying the same program voltage to the selected at least two string select lines.

14. The method of claim 12, wherein:
the program operation on the plurality of string select lines comprises a first program operation and a second program operation,
the plurality of string select lines are classified into at least two string select line groups;
the program operation is individually performed on the at least two string select line groups during the first program operation, and
the program operation is simultaneously performed on the at least two string select line groups during the second program operation.

15. The method of claim 14, wherein the first program operation includes applying a first program voltage to the plurality of string select lines, and
wherein the second program operation includes applying a second program voltage higher than the first program voltage to the plurality of string select lines.

16. The method of claim 15, further comprising:
performing a verify read operation on the selected at least two string select lines, wherein:
the verify read operation comprises a first verify read operation and a second verify read operation,
the first verify read operation corresponds to the first program operation, and the second verify read operation corresponds to the second program operation,
the verify read operation is individually performed on the at least two string select line groups during the first verify read operation, and
the verify read operation is simultaneously performed on the at least two string select line groups during the second verify read operation.

17. The method of claim 16, wherein:
the first verify read operation includes simultaneously applying a verify read voltage to corresponding string select lines within the same string select line group when the number of corresponding string select lines in the same string select line group is two or more, and
the verify read voltage for a string select line group corresponding to two or more string select lines is higher than a verify read voltage for a string select line group corresponding to a single string select line.

18. The method of claim 14, wherein the first program operation includes simultaneously applying a program voltage to corresponding string select lines within the same string select line group when the number of the corresponding string select lines of the same string select line group is two or more.

19. A storage device comprising:
a plurality of non-volatile memory devices comprising a plurality of cell strings disposed on a substrate; and
a solid-state drive (SSD) controller configured to control the plurality of non-volatile memory devices, wherein:
at least one of the plurality of non-volatile memory devices is configured to:
perform a program operation on a plurality of string select lines corresponding to one of the plurality of cell strings and arranged in a direction perpendicular to the substrate, and
simultaneously perform a program operation on at least two string select lines among the plurality of string select lines,
each of the plurality of cell strings includes a plurality of string select transistors, a plurality of memory cells, and one or more ground select transistors connected in series, and
each of the plurality of string select transistors is connected to a corresponding string select line of the plurality of string select lines.

20. The storage device of claim 19, wherein the same program voltage is simultaneously applied to the at least two string select lines when the program operation is simultaneously performed on the at least two string select lines.
